(19) United States
(12) Patent Application Publication
(10) Pub. No.: US 2026/0006754 A1
(43) Pub. Date: Jan. 1, 2026

(54) SMART POWER STAGE (SPS) BOARD WITH MAGNETICALLY ATTACHABLE HEATSINK ASSEMBLY

(71) Applicant: Aivres Systems Inc., San Jose, CA (US)

(72) Inventors: Zhuang-Xuan QUE, New Taipei City (TW); Chunying LU, Taipei (TW)

(21) Appl. No.: 19/319,672

(22) Filed: Sep. 4, 2025

Related U.S. Application Data
(63) Continuation-in-part of application No. 19/248,087, filed on Jun. 24, 2025.

(51) Int. Cl. H05K 7/20; H05K 9/00

(52) U.S. Cl. CPC H05K 7/20418; H05K 7/20154; H05K 7/20172; H05K 7/2049; H05K 7/20509; H05K 7/20909; H05K 9/0075

(57) ABSTRACT

An apparatus and method for thermal management of electronic devices are disclosed. A magnetic heatsink includes a thermally conductive base with vertical fins and one or more shielded magnet units having an exposed attachment face. A subset of fins form fan-receiving groups with inwardly curved extensions and a bottom slot bent upward to create a protruding lip, cooperating to provide lateral guidance and three-way mechanical locking of a micro fan module that also magnetically couples to the heatsink. A Smart Power Stage (SPS) board carries embedded magnet units and a board-to-board interface to magnetically and electrically engage a designated motherboard zone having a metal pad and connector, enabling tool-less installation, self-alignment and efficient heat transfer. Methods of configuring, servicing, and replacing the fan and SPS board are also described.

### CROSS-REFERENCE TO RELATED APPLICATION

This application is a continuation-in-part of U.S. patent application Ser. No. 19/248,087, entitled “MODULAR POWER STAGE BOARD FOR INTERCHANGEABLE SMART POWER STAGE MODULES,” filed Jun. 24, 2025, the entire disclosure of which is incorporated by reference herein. This application claims the benefit of priority to the foregoing application under 35 U.S.C. § 120.

### TECHNICAL FIELD

The disclosure relates to thermal management in electronic systems, particularly to heatsinks adapted for tool-less magnetic attachment of cooling and power modules. More specifically, it discloses shielded magnetic coupling structures, fin geometries that mechanically stabilize micro fans, and modular Smart Power Stage (SPS) boards that magnetically and electrically interface with a motherboard.

### BACKGROUND

In modern servers and high-performance computing platforms, voltage regulator modules (VRMs) supply tightly regulated power to CPUs, GPUs, and memory. Their power devices (e.g., MOSFETs, Smart Power Stages (SPS)) dissipate substantial heat under heavy load. Conventional cooling relies on passive metal fin heatsinks mounted to the motherboard with screws, clips, plastic snaps, or soldered brackets, and on chassis airflow to remove heat. These approaches complicate service, consume valuable board area for fasteners and keep-outs, and provide only passive cooling, which is often insufficient for transient thermal spikes or persistent hot spots. System-level fans improve bulk convection but are poorly suited to precise, localized cooling of small VRM hot zones.

Existing SPS solutions are typically soldered to the PCB, which limits design experimentation and slows fault isolation. Early SPS selection is often based on simulation rather than in-situ measurement; if the chosen rating or phase count proves inadequate during bring-up, redesign and re-layout can be required, extending schedules.

Accordingly, there remains a need for a thermal architecture that enables tool-less installation and service, supports targeted active cooling at VRM hot spots, and permits rapid swap-in evaluation of SPS power stages—while minimizing magnetic interference with nearby fans and circuitry and fitting within dense motherboard layouts.

### SUMMARY

In one general aspect, a magnetic heatsink assembly may include a heatsink base formed of a thermally conductive material and a plurality of fins that vertically extend from a top surface of the base. The assembly may further include one or more magnet units disposed in or on the heatsink base, each magnet unit defining an exposed attachment face configured to magnetically engage an external module. To confine magnetic flux and inhibit interference with nearby circuitry, each magnet unit may be surrounded by a magnetic shield on all non-mating faces while leaving the exposed attachment face uncovered.

In some implementations, the magnet units on the heatsink base may be arranged as a first set located along a side surface of the base to engage magnetic micro-fan cooling modules and a second set located along a bottom surface of the base to engage a motherboard for magnetic anchoring and, in certain cases, thermal coupling. The first set may be positioned adjacent to at least one fan-receiving fin group to enhance magnetic coupling to a received fan module. The micro-fan cooling module itself may include one or more magnet units on one or more mating faces and may be configured to magnetically couple to a complementary magnet unit of the heatsink assembly.

In some embodiments, the pair of fins that receives the fan provides additional mechanical retention. A subset of the fins may therefore form at least one fan-receiving fin group that defines an inter-fin channel between a left fan-receiving fin and a right fan-receiving fin. These two fins may be wider than adjacent fins, and each may include a side extension that curves inward toward the inter-fin channel. The inwardly curved side extensions define opposing concave guide surfaces that laterally engage the sidewalls of a fan module when it is inserted into the inter-fin channel. The heatsink base may further include a bottom slot located at a bottom-center region of the inter-fin channel, the slot having an edge bent upward to form a protruding lip that engages an underside portion of the fan module. In combination, the inwardly curved side extensions and the protruding lip may provide a three-way mechanical locking action that constrains the fan in left-right directions and against upward lift, thereby suppressing wobble, vibration, and positional shift during operation. In some variants, the fan module may include an underside recess configured to mechanically engage the protruding lip of the bottom slot.

In another aspect, the magnetic heatsink assembly may be used with a Smart Power Stage (SPS) board. The SPS board may include a substrate having a first surface and an opposite second surface; one or more SPS-module mounting sites on the first surface, each configured to receive and electrically connect to an SPS module; and a board-to-board electrical interface on the second surface configured to mate with a corresponding connector in a designated zone on a motherboard to provide power and control-signal transmission. The SPS board may further include at least one embedded magnet unit configured to magnetically attach the SPS board to the magnetic heatsink assembly to provide thermal coupling and/or to a designated zone on the motherboard that includes one or more metal pads for magnetic anchoring. The designated zone on the motherboard may additionally include a thermally conductive pad arranged to function as a heat spreader for the SPS board when magnetically anchored. A thermal conductive pad may also be disposed between a bottom surface of the heatsink base and a top surface of the SPS board to accommodate component tolerances and promote uniform heat transfer.

Materials and shielding options may be selected to optimize performance. The heatsink base and the fins may comprise aluminum or copper. The magnet units may comprise neodymium-iron-boron elements, and the magnetic shield may comprise a high-permeability soft-magnetic material (e.g., a soft-magnetic alloy) or, in some embodiments, a resin loaded with magnetic powder. These shielding structures may surround the magnet bodies on all faces other than the attachment face to confine magnetic flux away from adjacent circuitry and fan electronics.

In a further aspect, a method for configuring a heat-dissipation device may include providing a magnetic heatsink assembly having the thermally conductive base, vertically extending fins, and one or more magnet units with exposed attachment faces that are magnetically shielded on the non-mating faces; providing an SPS board having at least one embedded magnet unit and a board-to-board electrical interface; positioning the SPS board with respect to a motherboard that includes a designated zone with a mating connector; magnetically attaching the SPS board to the magnetic heatsink assembly and to the designated zone on the motherboard; and electrically mating the SPS board's board-to-board interface with the motherboard connector to provide power and control-signal transmission. The method may additionally include providing a micro-fan cooling module with one or more magnet units at a mating face and magnetically coupling the micro-fan to a magnet unit of the heatsink assembly; inserting the micro-fan into the inter-fin channel of a fan-receiving fin group so that the inwardly curved side extensions laterally guide the fan and an underside portion of the fan engages the protruding lip of the bottom slot to realize three-way mechanical locking; and disposing a thermal interface between the bottom surface of the heatsink base and the top surface of the SPS board.

These aspects may be implemented individually or in combination to provide modular, tool-less placement of cooling hardware and power-stage electronics, targeted convection over heatsink fins, and robust magnetic retention with controlled flux paths suitable for dense motherboard layouts.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates example schematic and physical layouts of a multiphase power delivery system using Smart Power Stage (SPS) modules to supply power to a CPU.

FIG. 2 illustrates a cross-sectional overview of magnetically attachable SPS board with integrated micro fan and heatsink assembly, in accordance with some embodiments.

FIG. 3 illustrates an example magnetic heatsink assembly, in accordance with some embodiments.

FIG. 4 illustrates example magnetic micro fans, in accordance with some embodiments.

FIG. 5 illustrates an example engagement between the magnetic heatsink assembly and the magnetic micro fans, in accordance with some embodiments.

FIG. 6A illustrates example top and bottom views of the magnetically attachable SPS board, in accordance with some embodiments.

FIG. 6B illustrates an example motherboard configuration for receiving the magnetically attachable SPS board, in accordance with some embodiments.

FIG. 7 illustrates an example configuration of a magnetically attachable SPS board with an integrated heatsink and micro fan assembly, in accordance with some embodiments.

FIG. 8 illustrates an example method for configuring a magnetically attachable SPS board with an integrated heatsink and micro fan assembly, according to one example embodiment.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

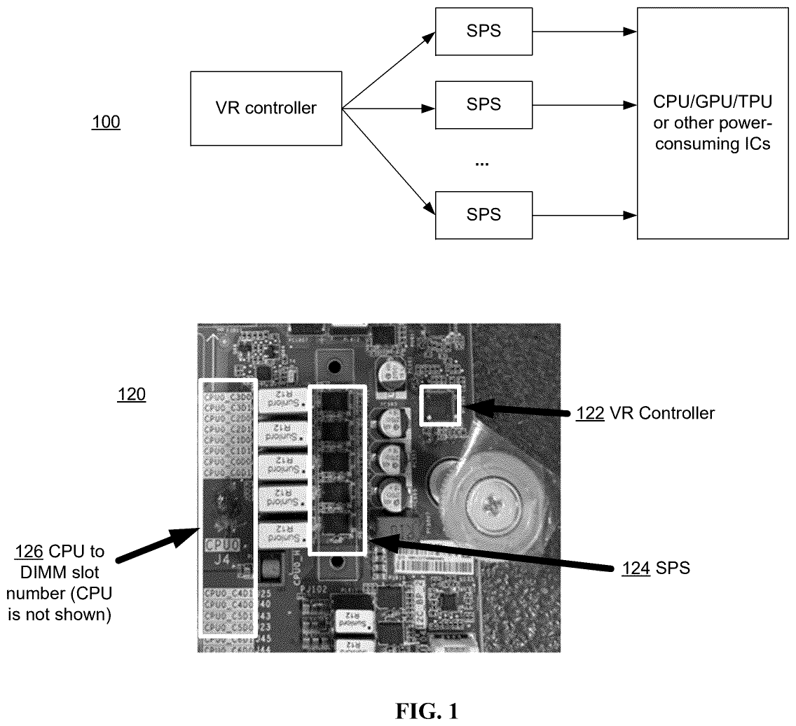

FIG. 1 illustrates example schematic and physical layouts of a multiphase power delivery system using Smart Power Stage (SPS) modules to supply power to a central processing unit (CPU), as an example.

As shown in FIG. 1, diagram 100 depicts a voltage regulation architecture in which a voltage regulator (VR) controller is electrically coupled to a plurality of SPS modules. The VR controller outputs control signals to the SPS modules, which operate as individual phases in a multiphase conversion system, collectively regulating current supplied to a high-performance load such as a CPU, GPU, or other integrated circuit.

FIG. 1 also includes a real-world implementation shown in image 120, which illustrates a motherboard with the VR controller 122 mounted at a first location, a group of SPS modules 124 mounted at a second location, and a group of DIMM slots 126 associated with a CPU socket (not shown in FIG. 1) at a third location. The VR controller 122 communicates with the SPS modules 124 through traces in the printed circuit board (PCB), transmitting pulse-width modulation (PWM) or equivalent control signals. The SPS modules 124 convert incoming supply voltage (e.g., 12 V) into a low-voltage, high-current output (e.g., 1 V) suitable for the CPU.

While this VR-SPS-CPU configuration is widely adopted, it presents thermal and mechanical challenges in practice. Each SPS module 124 can generate significant heat under heavy load, yet conventional solutions rely on heatsinks screwed or clamped to the board, supplemented only by system-level airflow. Such arrangements are difficult to service, occupy valuable PCB area with fasteners and keep-outs, and often provide only passive dissipation that cannot respond effectively to transient hotspots.

In addition, SPS modules are traditionally soldered in place, which complicates experimentation, debugging, or replacement during development. Rework of individual SPS devices can be labor-intensive and risky in dense layouts, potentially damaging adjacent traces or components.

Subsequent figures will introduce improvements in the form of a magnetic heatsink assembly, magnetically attachable micro fan modules, and a magnetically attachable SPS board. Together, these structures (in some embodiments, some of these structures) enable tool-less installation, enhanced thermal coupling, and modular replacement of SPS modules, addressing both the cooling inefficiency and the lack of deployment flexibility in conventional designs.

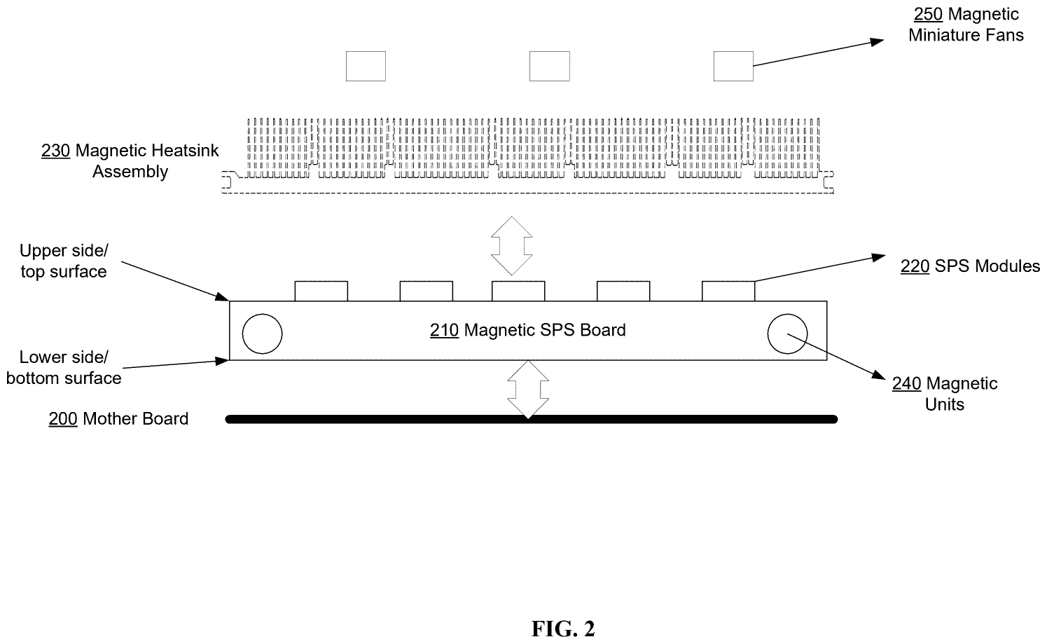

FIG. 2 illustrates a cross-sectional overview of magnetically attachable SPS board with integrated micro fan and heatsink assembly, in accordance with some embodiments.

In the example shown, a motherboard 200 provides the host platform for a multiphase power delivery system. A magnetic SPS board 210 (a magnetic modular power stage board) is positioned above the motherboard 200 and carries a plurality of Smart Power Stage (SPS) modules 220 on its upper side/top surface. The SPS modules 220 operate as individual phases under control of a VR controller (not shown in FIG. 2) to supply regulated current to a processor socket region.

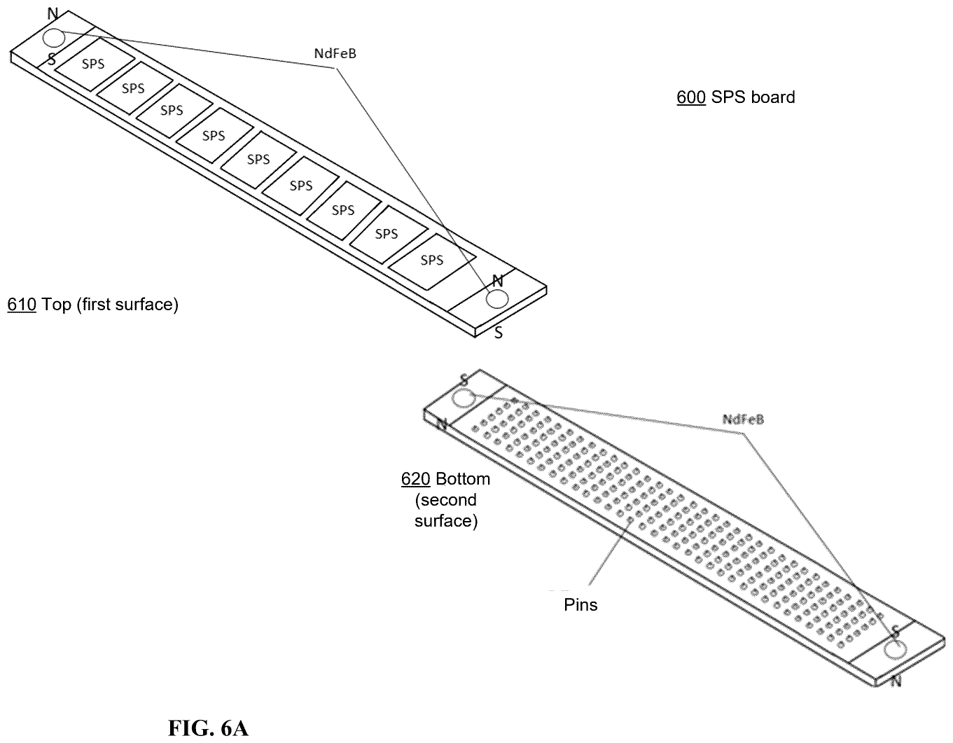

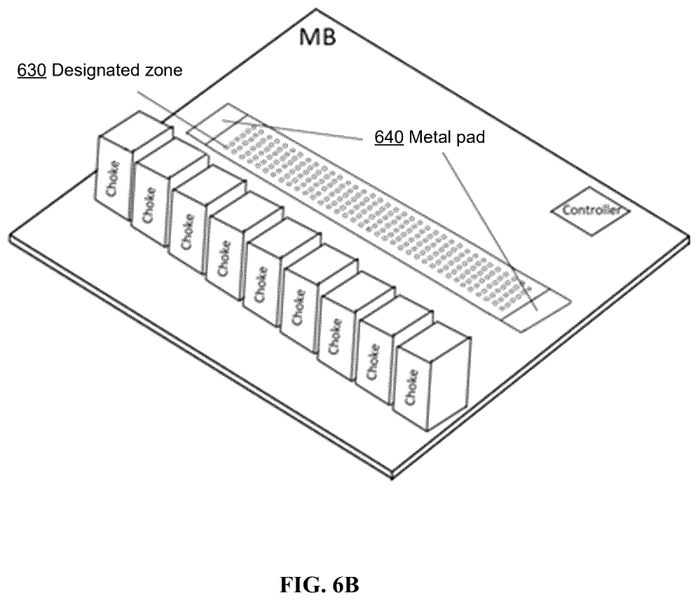

In some embodiments, the SPS board 210 may further include magnetic units 240 that cooperate with designated anchoring features on the motherboard 200 to enable tool-less placement, self-alignment, and retention. In some embodiments, the anchoring features may include one or more metal pads on the motherboard 200; when brought into proximity, magnetic coupling positions the SPS board 210 for engagement with a board-to-board electrical connector (not shown in FIG. 2, but shown in FIGS. 6A and 6B). The magnetic units 240 may be shielded on sides other than their exposed attachment faces to confine magnetic flux away from nearby signal traces and components.

As shown, arranged above the SPS modules 220 is a magnetic heatsink assembly 230. The heatsink assembly 230 may include a thermally conductive base with vertically extending fins and is configured to magnetically engage the SPS board 210. One or more thermal interface layers can be disposed between the heatsink assembly 230 and the tops of the SPS modules 220 to promote efficient heat transfer and to accommodate height tolerances across the module array.

In some embodiments, a set of magnetic micro fans 250 may be configured above the heatsink assembly 230. Each fan 250 may be configured to magnetically attach to the heatsink assembly 230 so that active airflow can be placed where needed over identified hotspots. In certain implementations the fans 250 include their own magnetic units (optionally shielded) to cooperate with complementary attachment points on the heatsink assembly 230, allowing the fans 250 to be repositioned or removed without tools.

The vertical stack indicated by the arrows in FIG. 2 shows the cooperative roles of the assemblies: the SPS board 210 is magnetically anchored with respect to the motherboard 200 for electrical interfacing, the magnetic heatsink assembly 230 is brought into thermal contact with the SPS modules 220, and the magnetic micro fans 250 provide targeted convection over the fins. This layered architecture supports modular replacement of power stages, tool-less installation of cooling hardware, and flexible deployment of localized fans-all within the spatial constraints of dense motherboard layouts.

Although FIG. 2 depicts a simplified cross-section for clarity and is not to scale, the same arrangement can accommodate variations such as different SPS module counts, alternative fin layouts, and different placements or polarities of the magnetic units 240. In some embodiments the SPS board 210 is magnetically coupled to at least one of the heatsink assembly 230 and the motherboard 200; in other embodiments it is simultaneously coupled to both to improve mechanical stability and thermal conduction paths.

In some embodiments, not all components shown in FIG. 2 are required. For example, the magnetic micro fans 250 are optional and may be omitted where chassis airflow satisfies the thermal budget, with the magnetic heatsink assembly 230 providing passive dissipation. In other implementations, installation steps may be staged—e.g., the SPS board 210 may be magnetically attached and electrically mated to the motherboard 200 prior to installing the heatsink assembly 230 and, if used, the micro fans 250.

For avoidance of doubt, FIG. 2 is intended to provide a high-level overview of the cooperating components (the motherboard 200, the magnetic SPS board 210 with SPS modules 220 and magnetic units 240, the magnetic heatsink assembly 230, and the magnetic micro fans 250) without limiting the detailed mechanical geometries or electrical interfaces described with respect to subsequent figures.

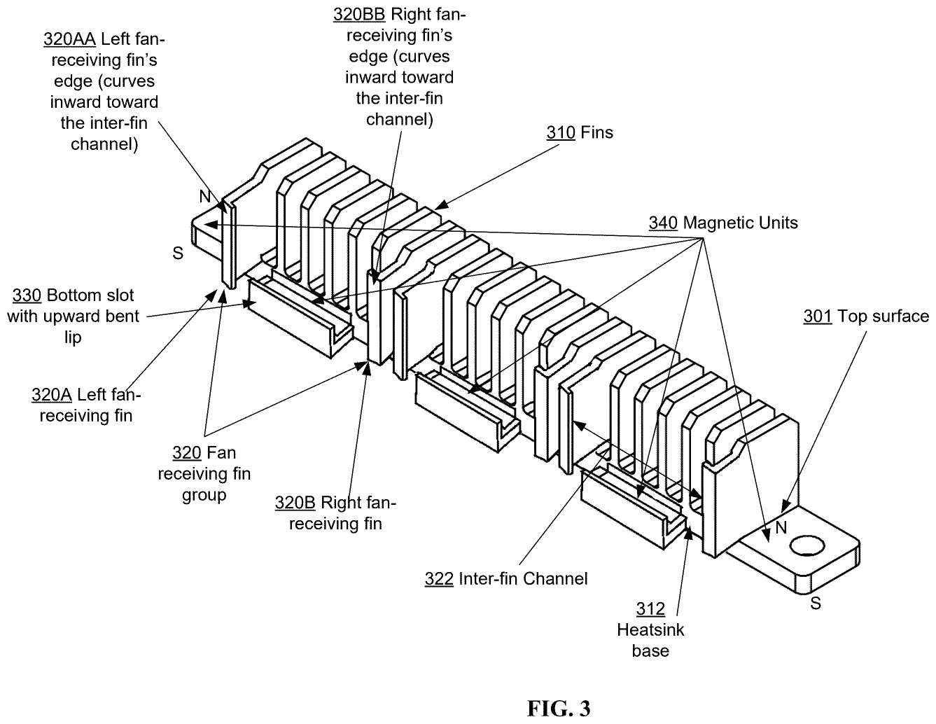

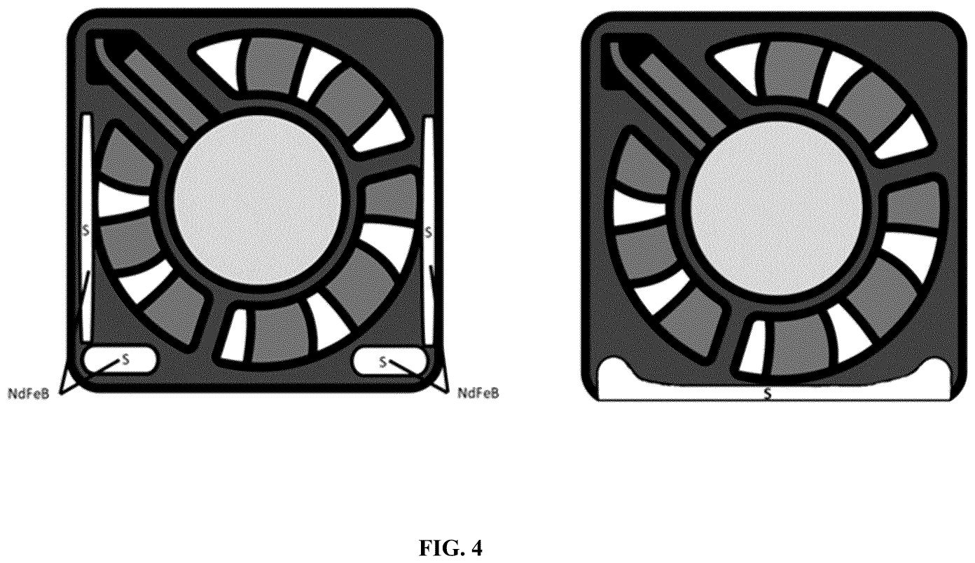

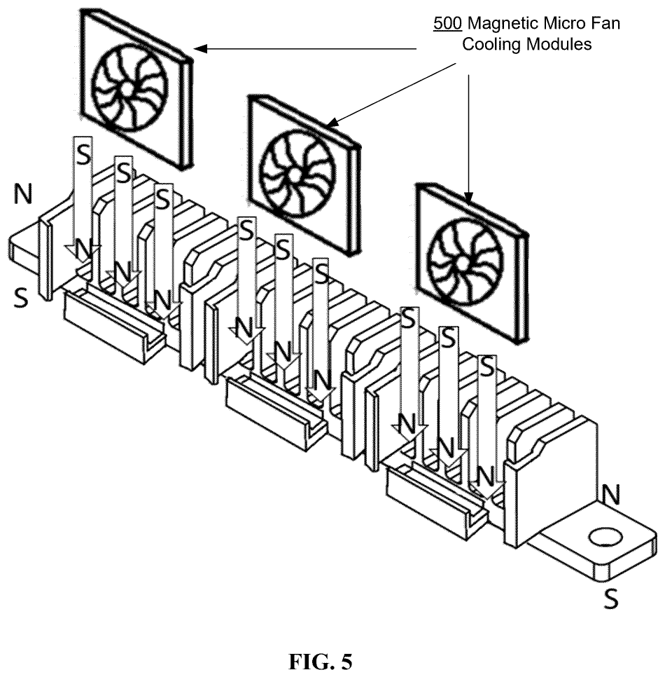

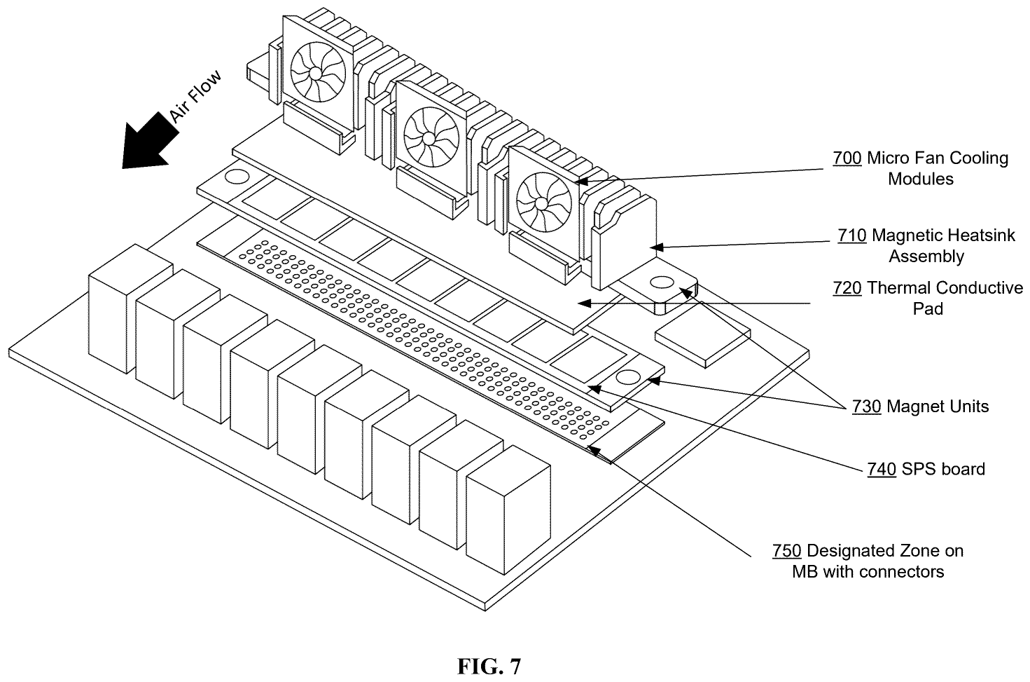

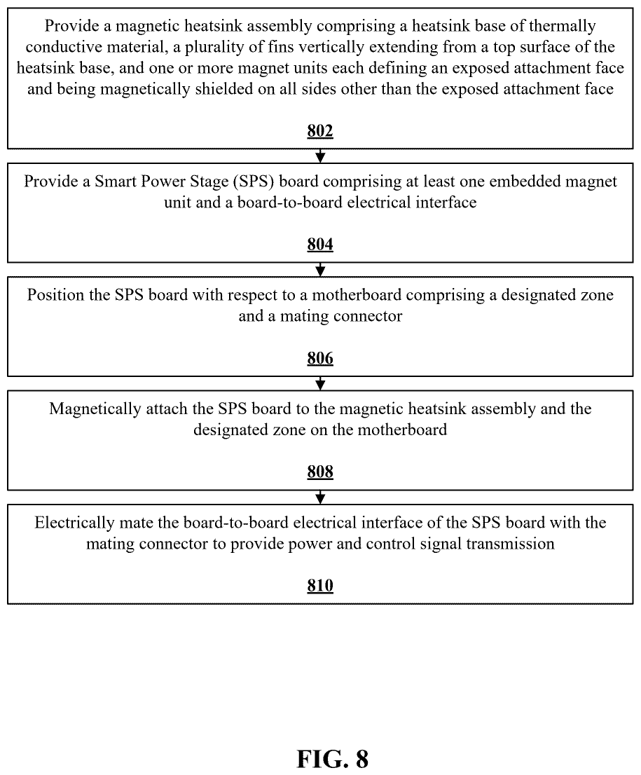

The subsequent figures present example constructions of the magnetic heatsink assembly 230 (FIG. 3), the magnetic micro fans 250 (FIG. 4) and their engagement with the heatsink assembly 230 (FIG. 5), as well as example layouts of the SPS board 210 (FIG. 6A) and a corresponding motherboard region for receiving it (FIG. 6B), culminating in an example integrated configuration (FIG. 7) and a method of assembly (FIG. 8).

FIG. 3 illustrates an example magnetic heatsink assembly, in accordance with some embodiments.

In the example shown in FIG. 3, a plurality of fins 310 vertically extends from a top surface 301 of a heatsink base 312. To accommodate micro fans for proactive heat dissipation, a subset of the fins 310 may form at least one fan-receiving fin group 320 (FIG. 3 shows three such groups). Each fan-receiving fin group 320 may include a left fan-receiving fin 320A and a right fan-receiving fin 320B that are wider (i.e., the increased lateral width provided by side extensions 320AA and 320BB) than adjacent fins (e.g., the fins in-between the left and right fan-receiving fins) and that define therebetween an inter-fin channel. The left fan-receiving fin 320A may have a side extension (320AA) that curves inward toward the inter-fin channel 322, and the right fan-receiving fin 320B may have a side extension (320BB) that curves inward toward the inter-fin channel 322, so that the two side extensions define opposing concave guide surfaces configured to laterally engage sidewalls of a fan module received in the inter-fin channel 322 (e.g., the micro fan cooling module 250 of FIG. 2).

In some embodiments, the heatsink base 312 may further include a bottom slot 330 located at a bottom center region of the inter-fin channel 322 between the left and right fan-receiving fins 320A and 320B of each fan-receiving fin group 320. An edge of the bottom slot 330 may be bent upward to form a protruding lip configured to engage an underside portion of a micro fan cooling module received in the inter-fin channel. In operation, the inwardly curved side extensions of the left and right fan-receiving fins 320A and 320B together with the protruding lip of the bottom slot 330 may provide three-way mechanical locking that constrains the micro fan cooling module laterally (left-right) and vertically (upward lift), thereby suppressing wobble, vibration, and positional shift during operation.

In some embodiments, one or more magnet units 340 may be disposed in or on the heatsink base 312. Each magnet unit 340 may define an exposed attachment face configured to magnetically engage an external module (e.g., a fan cooling module) and may be surrounded by a magnetic shield on all sides except the exposed attachment face to inhibit magnetic interference with nearby components. In some embodiments, a first set of the magnet units 340 may be disposed on a side surface of the heatsink base 312 (e.g., proximate to the fan-receiving fin groups 320) to magnetically couple to complementary magnet units of a micro fan cooling module 250. For example, a magnet unit 340 may be disposed within the bottom slot 330 and/or the insides of the left and right fan-receiving fins 320A and 320B. In other embodiments or additionally, a second set of magnet units 340 may be disposed on a bottom surface of the heatsink base 312 to magnetically couple to metal pads or designated anchoring features on an SPS board (if the heatsink engages directly on top of the SPS board) or a motherboard (if the heatsink engages directly on a motherboard) for positional retention (the bottom-surface units are not visible in this perspective). The “N” and “S” indicators in FIG. 3 illustrate example pole orientations; shielding structures are omitted from the drawing for clarity.

The fins 310 and the heatsink base 312 may be formed of thermally conductive material (e.g., aluminum or copper) and may be integrally formed or bonded. In some embodiments, a thermal conductive material (e.g., one or more thermal conductive pads) may be disposed between a bottom surface of the heatsink base 312 and a top surface of an underlying SPS board or motherboard to promote uniform heat transfer and accommodate component height tolerances.

In some embodiments, when a fan module (e.g., the micro fan cooling module 250) is installed, the fan module's magnet units may magnetically couple to the first set of magnet units 340 while the inwardly curved fin side extensions of the fan-receiving groups 320 and the protruding lip of the bottom slot 330 provide the mechanical retention described above. This cooperative engagement may permit tool-less installation and repositioning of the fan module while maintaining stable airflow over the fins 310.

In some embodiments, the heatsink assembly is used as the sole heat dissipation component without magnetic micro fans 250. In this case, all of the fins 310 may be uniformly shaped, of substantially equal thickness and height, and vertically configured across the heatsink base 312 to maximize passive surface area and conduction to ambient airflow. In such embodiments, fan-receiving fin groups 320 and the bottom slot 330 may be omitted, and the magnet units 340 on the two ends of the heatsink base 312 may be used primarily for board-level anchoring or for coupling the heatsink assembly to another passive structure, e.g., the underlying SPS board.

Although FIG. 3 presents one representative configuration, the number and spacing of fan-receiving fin groups 320, the geometry of the side extensions on the fan-receiving fins 320A, the dimensions of the bottom slot 330, and the placement and polarization of the magnet units 340 may vary across embodiments without departing from the teachings set forth herein. By way of example, in some embodiments one or more magnet units 340 may be positioned laterally within, or immediately behind, the inwardly curved side extensions of the fan-receiving fins 320A so as to couple to complementary magnets on a fan cooling module, while no magnet unit 340 is needed at or beneath the bottom slot 330. In such cases, the side-located magnetic coupling together with the three-way mechanical locking formed by the opposing concave guide edges (320AA and 320BB) and the upward-bent lip of the bottom slot 330 may be sufficient to stabilize the fan against airflow-induced lift and operational vibration. The magnet units 340 may be placed in other manner, provided the resulting magnetic retention, optionally in concert with the mechanical features of the fan-receiving fin group 320 and the bottom slot 330, maintains the fan in position during expected airflow forces and vibration.

FIG. 4 illustrates example configurations of a micro fan cooling module 250 (also referred to as a magnetic miniature fan) having magnet units disposed on one or more mating faces, in accordance with some embodiments.

In the left-hand depiction of FIG. 4, the micro fan cooling module 250 includes elongated magnet units disposed as vertical strips along opposing side faces of the fan housing, as well as a pair of magnet units disposed at the bottom corners of the fan housing (collectively called side-face magnet units). These side-face magnet units may be neodymium-iron-boron (NdFeB) elements and may be magnetically shielded on non-mating faces to confine magnetic flux away from neighboring components such as the fan motor electronics. When the micro fan cooling module 250 is inserted into the inter-fin channel defined by the fan-receiving fin group 320 of FIG. 3, the side-face magnet units of the micro fan cooling module 250 may magnetically couple to the first set of magnet units 340 on the side surface of the magnetic heatsink assembly 230 (e.g., within the curved edges of the fan-receiving fins 320 and/or the bottom slot 330). The side coupling may be used in concert with the mechanical features of the fan-receiving fin group 320 (e.g., the opposing concave guide surfaces formed by the inwardly curved side extensions of the left and right fan-receiving fins 320A and the bottom slot 330 with its upward-bent lip) to realize the three-way retention described above.

In the right-hand depiction of FIG. 4, the micro fan cooling module 250 includes a magnet unit arranged as a horizontal strip proximate the bottom of the fan housing. In some embodiments, this bottom magnet unit may be disposed only on a side face of the micro fan cooling module 250 (i.e., at the lower region of the side wall) to mate to a corresponding side-surface magnet unit 340 of the heatsink assembly 230. In other embodiments, the bottom magnet unit may wrap around at least a portion of both the side face and the bottom face of the micro fan cooling module 250, forming an L-shaped or U-shaped magnetic strip. The wrap-around configuration may be used to couple simultaneously to a magnet target on the side surface of the heatsink and to a magnetic target located within to the bottom slot 330 of the heatsink. In either case, the magnetic attachment is intended to cooperate with the three-way mechanical locking provided by the fan-receiving fin group 320 and the bottom slot 330 to resist airflow-induced lift and operational vibration.

The placements shown in FIG. 4 are merely illustrative. Other dispositions of the fan's magnet units, such as discrete blocks at diagonally opposite corners, perimeter arrays, or multipole strips tuned for self-alignment, may be used, provided they supply sufficient magnetic attachment force to couple the micro fan cooling module 250 to the magnet units 340 of the magnetic heatsink assembly 230 while the pair of fins in the fan-receiving fin group 320 provides lateral guidance and retention.

FIG. 5 illustrates an example engagement between the magnetic heatsink assembly and the magnetic micro fan cooling modules 500, in accordance with some embodiments. As shown, each magnetic micro fan cooling module 500 may be aligned with an inter-fin channel defined by a corresponding fan-receiving fin group 320. The downward arrows indicate the insertion direction: the magnetic micro fan cooling module 500 may be guided between the widened left and right fan-receiving fins (e.g., 320A and 320B in FIG. 3) whose inwardly curved side extensions form opposing concave guide surfaces. This guidance may automatically square the magnetic micro fan cooling module 500 to the fins and center the fan in the inter-fin channel.

During insertion, magnet units on the magnetic micro fan cooling module 500 may magnetically couple to magnet units disposed in or on the heatsink base. The “N” and “S” legends schematically denote example polarities; in some embodiments the magnet units adjacent to the fin group are patterned with alternating polarities to produce a self-centering restoring force as the magnetic micro fan cooling module 500 approaches. Depending on the fan configuration (see FIG. 4), the coupling may occur via side-face magnets on the fan 500 to side-surface magnet units, and/or via a wrap-around magnet on the fan that additionally couples to a magnetic target proximate the bottom slot.

When fully seated, an underside portion of the magnetic micro fan cooling module 500 may engage the upward-bent lip of the bottom slot (e.g., 330 in FIG. 3) while the opposing concave guide surfaces of the fins (e.g., 320A and 320B in FIG. 3) flank the fan's sidewalls. In combination with the magnetic attraction, these features may provide the three-way mechanical locking described above (constraining lateral motion (left-right) via the curved side extensions and constraining upward lift via the lip) thereby suppressing wobble, vibration, and positional shift under airflow.

FIG. 5 depicts three fans 500 engaging three fan-receiving fin groups 320 for clarity; more or fewer fans may be employed, and the spacing, polarity pattern, and placement of magnet units 340 may be adjusted to meet airflow and structural requirements.

FIG. 6A illustrates example top and bottom views of a magnetically attachable SPS board 600, in accordance with some embodiments. The board 600 provides both the electrical interface to a motherboard and magnetic features that enable tool-less coupling to the magnetic heatsink assembly (230 in FIGS. 2-5) and/or to a designated anchoring zone on the motherboard (200 in FIG. 2).

In the top view 610, a row of SPS module mounting sites is shown populated with SPS modules (200 in FIG. 2) arranged longitudinally along the substrate. Each mounting site may include conductive pads and vias configured to receive and electrically connect an SPS module using surface-mount attachment or a socketed interface. Proximate the two ends of the SPS board 600 are embedded magnet units (labeled “NdFeB” in the figure) that define exposed attachment faces. In some embodiments these end magnets are implemented as through-cylinders captured in shielded sleeves so that an attachment face is exposed at the top view 610 and at the bottom view 620; in other embodiments separate top-side and bottom-side magnets are used. The magnets may be neodymium-iron-boron (NdFeB) and may be surrounded by a magnetic shield on all non-mating faces to confine magnetic flux away from nearby SPS control and gate-drive circuitry. The top-side attachment face may be used to magnetically couple the SPS board 600 to the underside of the magnetic heatsink assembly (230 in FIG. 2) for thermal coupling.

In the bottom view 620, a board-to-board electrical interface is provided as a dense array of pins (labeled “Pins” in FIG. 6A) distributed over a contact region of the second surface. The array may include spring-loaded pogo pins, press-fit pins, or a land-grid of plated pads configured to mate with a complementary connector or contact field on the motherboard (200 in FIG. 2), thereby providing both high-current power paths and control/telemetry signal connections. The array may be segmented into power and signal zones to improve current sharing and signal integrity. Also visible at the ends of the bottom view 620 are embedded magnet units (NdFeB) with exposed attachment faces arranged to magnetically anchor to metal pads in a designated zone of the motherboard; in some implementations those metal pads are thermally conductive so that, when anchored, the motherboard pad functions as a heat spreader for the SPS board.

The polarity markings “N/S” in FIG. 6A indicate example orientations that may be chosen to promote self-alignment with opposing magnets or ferromagnetic pads on the heatsink assembly and the motherboard. The number, size, and placement of the magnet units may be varied to achieve the desired holding force and alignment behavior, provided that each magnet unit is magnetically shielded on all sides except its exposed attachment face to inhibit magnetic interference with the SPS modules and the pin field of the board-to-board interface.

While FIG. 6A depicts eight SPS modules 220 for illustration, other phase counts, module footprints, and connector densities may be used. Likewise, the board-to-board interface may be realized with alternative solderless structures such as a compression land-grid array or edge-connector tab, and the magnetic attachment may be used with either or both of the heatsink assembly 230 and the motherboard 200, as dictated by mechanical and thermal design goals.

FIG. 6B illustrates an example motherboard (MB) configuration for receiving the magnetically attachable SPS board, in accordance with some embodiments. As shown, a designated zone 630 is reserved on the motherboard to mate with the board-to-board electrical interface on the underside of the SPS board (see pins in FIG. 6A, bottom view 620). The designated zone 630 may include a high-density contact field implemented as a compression land-grid, spring-pin socket, or equivalent connector that provides both high-current power paths and low-level control/telemetry signals between the motherboard and the SPS modules mounted on the SPS board.

At opposite ends of the designated zone 630 shown in FIG. 6B, metal pads 640 are provided to cooperate with the embedded magnet units on the SPS board. Each metal pad 640 may be formed of a ferromagnetic or soft-magnetic material and may be plated for corrosion resistance. When the SPS board is placed over the designated zone 630, the exposed attachment faces of the SPS board's end magnets magnetically anchor to the metal pads 640 to establish positional retention and self-alignment. In some embodiments, at least one metal pad 640 is thermally conductive and coupled to copper planes in the motherboard so that, when anchored, the pad functions as a local heat spreader for the SPS board.

The controller in FIG. 6B may refer to a voltage-regulator (VR) controller responsible for generating PWM or equivalent control signals for the multiphase power stage. Adjacent to the designated zone 630 is a row of components (labeled “Choke”), which in this context refer to inductors used in the VRM output filter. Each choke stores energy and smooths the switching current from a corresponding SPS phase, cooperating with output capacitors (not shown) to deliver low-ripple DC current to a load such as a CPU.

FIG. 7 illustrates an example configuration of a magnetically attachable SPS board 740 with an integrated heatsink and micro fan assembly, in accordance with some embodiments. As shown, the magnetic heatsink assembly 710 (as described in FIG. 3) may include a thermally conductive heatsink base (e.g., aluminum or copper) from which a plurality of fins vertically extend. One or more magnet units 730 may be disposed in or on the base with an exposed attachment face for coupling external modules; each magnet unit 730 may be magnetically shielded on all sides other than the attachment face (e.g., by a high-permeability soft-magnetic alloy or a resin loaded with magnetic powder) to confine magnetic flux away from nearby circuitry.

In some embodiments, a first set of magnet units 730 may be located along a side surface of the heatsink base to engage magnetic micro fan cooling modules 700. A second set of magnet units 730 may be located on the bottom surface of the base to engage a motherboard or other support. The heatsink fins may define one or more fan-receiving fin groups that include left and right fins wider than adjacent fins and shaped with inwardly curved side extensions that create opposing concave guide surfaces. Each group may further include a bottom slot whose edge is bent upward to form a protruding lip. When a micro fan cooling module 700 (as shown in FIG. 4) with magnet units on one or more mating faces is inserted into a fin group, the side extensions provide lateral guidance and the lip engages an underside recess of the fan 700, such that the curved extensions (i.e., the fan-receiving groups) and the lip cooperate with the magnetic coupling to provide three-way mechanical locking that suppresses wobble, vibration, and lift during operation. In some embodiments, the side-surface magnet units are positioned adjacent the fan-receiving fin groups to enhance coupling strength and self-alignment.

The assembly may further include a Smart Power Stage (SPS) board 740 as shown in FIGS. 6A and 6B. The SPS board 740 may provide a substrate having a first surface with one or more SPS-module mounting sites (each site configured to receive and electrically connect an SPS module) and a second, opposite surface carrying a board-to-board electrical interface (e.g., a high-density pin or pad field) that mates with a complementary connector in a designated zone on a motherboard for power and control signaling. The SPS board 740 may include embedded magnet units configured to magnetically attach to (i) the heatsink assembly for thermal coupling and/or (ii) a designated zone 750 on the motherboard that provides one or more ferromagnetic metal pads for magnetic anchoring. At least one of the metal pads in the designated zone may be thermally conductive and tied to board copper to function as a local heat spreader for the SPS board when anchored. A thermal conductive pad 720 may be disposed between the bottom of the heatsink base and the top of the SPS board to equalize contact and improve heat transfer.

In some implementations, the magnet units 730 on the above-mentioned components may be neodymium-iron-boron elements, the shields may be soft-magnetic alloys (e.g., Ni—Fe) or magnetically loaded resins, and the base/fins may be formed of aluminum or copper. The magnetic fans may use side-face strips, wrap-around L- or U-shaped strips, or discrete corner magnets, provided sufficient attachment force is achieved to maintain position under airflow and vibration. The arrangement shown supports tool-less installation, modular replacement of power stages, targeted convection over the fins by localized micro fans, and robust magnetic/thermal coupling to the motherboard within dense VRM layouts.

FIG. 8 illustrates an example method for configuring a magnetically attachable SPS board with an integrated heatsink and micro fan assembly, according to one example embodiment. In some implementations, one or more blocks of FIG. 8 may be performed by a device or by an operator using the device.

As shown in FIG. 8, process 800 may include providing a magnetic heatsink assembly having a heatsink base of thermally conductive material, a plurality of fins vertically extending from a top surface of the heatsink base, and one or more magnet units each defining an exposed attachment face and being magnetically shielded on all sides other than the exposed attachment face (block 802). For example, the device or the operator using the device may provide such a magnetic heatsink assembly as described above.

Process 800 may further include providing a Smart Power Stage (SPS) board having at least one embedded magnet unit and a board-to-board electrical interface (block 804). For example, the device or the operator using the device may provide the SPS board with the embedded magnet unit(s) and board-to-board interface.

Process 800 may also include positioning the SPS board with respect to a motherboard having a designated zone with a mating connector (block 806). For example, the device or the operator using the device may position the SPS board relative to the designated zone and the mating connector.

Process 800 may then include magnetically attaching the SPS board to the magnetic heatsink assembly and to the designated zone on the motherboard (block 808). For example, the device or the operator using the device may perform the magnetic attachment as described above.

Process 800 may include electrically mating the board-to-board electrical interface of the SPS board with the mating connector to provide power and control signal transmission (block 810). For example, the device or the operator using the device may electrically mate the SPS board's interface with the motherboard connector.

In some implementations, process 800 further includes providing a micro fan cooling module having one or more magnet units at a mating face and magnetically coupling the micro fan cooling module to a magnet unit of the magnetic heatsink assembly, where the fan's magnet units are magnetically shielded on all sides other than the mating face.

In another implementation, alone or in combination with the foregoing, the magnetic heatsink assembly includes at least one fan-receiving fin group defining an inter-fin channel between left and right fan-receiving fins, each having an inwardly curved side extension. The method further includes inserting a micro fan cooling module into the inter-fin channel so that the inwardly curved side extensions laterally guide the module, and engaging an underside portion of the module with a protruding lip of a bottom slot located at a bottom center region of the inter-fin channel to provide three-way mechanical locking.

In a further implementation, alone or in combination with the above, process 800 includes disposing a thermal interface between a bottom surface of the heatsink base and a top surface of the SPS board.

Although FIG. 8 shows example blocks of process 800, in some implementations the process may include additional blocks, fewer blocks, different blocks, or blocks arranged in a different order than depicted in FIG. 8. Additionally, two or more of the blocks may be performed in parallel.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuitry.

When the functions disclosed herein are implemented in the form of software functional units and sold or used as independent products, they can be stored in a processor executable non-volatile computer readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, wherein the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of exemplary methods described herein may be performed, at least partially, by an algorithm. The algorithm may be comprised in program codes or instructions stored in a memory (e.g., a non-transitory computer-readable storage medium described above). Such an algorithm may comprise a machine learning algorithm. In some embodiments, a machine learning algorithm may not explicitly program computers to perform a function but can learn from training data to make a prediction model that performs the function.

The various operations of exemplary methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A magnetic heatsink assembly comprising:
a heatsink base of thermally conductive material;
a plurality of fins extending from a top surface of the heatsink base; and
one or more magnet units disposed in or on the heatsink base and defining an exposed attachment face configured to magnetically engage an external module, each of the one or more magnet units being surrounded by a magnetic shield on all sides except for the exposed attachment face to inhibit magnetic interference with nearby components.

2. The magnetic heatsink assembly of claim 1, wherein the one or more magnet units disposed in or on the heatsink base comprises:
a first set of magnet units disposed on a side surface of the heatsink base for engaging with magnetic micro fans; and
a second set of magnet units disposed on a bottom surface of the heatsink base for engaging with the motherboard.

3. The magnetic heatsink assembly of claim 1, further comprising:
a micro fan cooling module comprising one or more additional magnet units disposed on one or more mating faces of the micro fan cooling module, and
the micro fan cooling module being configured to magnetically couple to one of the one or more magnet units of the heatsink assembly.

4. The magnetic heatsink assembly of claim 3, wherein the micro fan cooling module is further configured to be received between a pair of fins in the plurality of fins so that the pair of fins provide lateral guidance and retention of the micro fan cooling module, in addition to the magnetic coupling between the one or more additional magnet units of the micro fan and the one or more magnet units of the heatsink assembly.

5. The magnetic heatsink assembly of claim 1, wherein the plurality of fins comprise a subset of the fins forming at least one fan-receiving fin group, each of the at least one fan-receiving fin group comprising:
a left fan-receiving fin and a right fan-receiving fin that are wider than fins adjacent thereto and that define therebetween an inter-fin channel;
the left fan-receiving fin having a side extension that curves inward toward the inter-fin channel; and
the right fan-receiving fin having a side extension that curves inward toward the inter-fin channel;
wherein the side extensions of the left fan-receiving fin and the right fan-receiving fin define opposing concave guide surfaces that laterally engage sidewalls of a fan module received in the inter-fin channel.

6. The magnetic heatsink assembly of claim 5, wherein the heatsink base further comprises:
a bottom slot located at a bottom center region of the inter-fin channel between the left and right fan-receiving fins of each fan-receiving fin group, and
the bottom slot having an edge bent upward to form a protruding lip configured to engage an underside portion of a micro fan cooling module received in the inter-fin channel so that the inwardly curved side extensions and the protruding lip together provide three-way mechanical locking for the micro fan cooling module.

7. The magnetic heatsink assembly of claim 6, wherein the three-way mechanical locking constrains the micro fan cooling module in left-right directions via the inwardly curved side extensions and in an upward direction via the protruding lip, thereby suppressing wobble, vibration, and positional shift of the micro fan cooling module during operation.

8. The magnetic heatsink assembly of claim 1, wherein the magnetic heatsink assembly is configured to magnetically engage a Smart Power Stage (SPS) board, the SPS board comprising:
a substrate having a first surface and a second surface opposite to the first surface;
one or more SPS module mounting sites disposed on the first surface of the substrate, each mounting site configured to receive and electrically connect to an SPS module;
a board-to-board electrical interface disposed on the second surface of the substrate, the board-to-board electrical interface configured to mate with a designated zone on a motherboard to provide power and control signal transmission; and
at least one embedded magnet unit configured to magnetically attach the SPS board to at least one of (i) the magnetic heatsink assembly to provide thermal coupling and (ii) one or more metal pads of the designated zone on the motherboard for magnetic anchoring.

9. The magnetic heatsink assembly of claim 8, wherein the designated zone on the motherboard further comprises a thermally conductive pad arranged to function as a heat spreader for the SPS board when the SPS board is magnetically anchored thereto.

10. The magnetic heatsink assembly of claim 1, wherein the magnetic shield surrounds the magnet on all faces other than the attachment face.

11. The magnetic heatsink assembly of claim 1, wherein
the magnetic shield comprises a soft magnetic alloy or a resin loaded with magnetic powder to confine magnetic flux away from adjacent circuitry.

12. The magnetic heatsink assembly of claim 8, further comprising:
a thermal conductive pad disposed between a bottom surface of the heatsink base and a top surface of the SPS board.

13. The magnetic heatsink assembly of claim 1, wherein the one or more magnet units comprise neodymium-iron-boron magnets and the magnetic shield comprises a high-permeability soft magnetic material.

14. The magnetic heatsink assembly of claim 1, wherein the heatsink base and the plurality of fins comprise aluminum or copper.

15. The magnetic heatsink assembly of claim 2, wherein the first set of magnet units on the side surface is positioned adjacent to at least one fan-receiving fin group to enhance magnetic coupling to a received fan module.

16. The magnetic heatsink assembly of claim 6, wherein the fan module comprises an underside recess configured to mechanically engage the protruding lip of the bottom slot.

17. A method for configuring a heat dissipation device, comprising:
providing a magnetic heatsink assembly comprising a heatsink base of thermally conductive material, a plurality of fins extending from a top surface of the heatsink base, and one or more magnet units each defining an exposed attachment face and being magnetically shielded on all sides other than the exposed attachment face;
providing a Smart Power Stage (SPS) board comprising at least one embedded magnet unit and a board-to-board electrical interface;
positioning the SPS board with respect to a motherboard comprising a designated zone;
magnetically attaching the SPS board to the magnetic heatsink assembly and the designated zone on the motherboard; and
electrically mating the board-to-board electrical interface of the SPS board with the designated zone to provide power and control signal transmission.

18. The method of claim 17, further comprising:
providing a micro fan cooling module comprising one or more magnet units at a mating face and magnetically coupling the micro fan cooling module to a magnet unit of the magnetic heatsink assembly, the magnet units of the micro fan cooling module being magnetically shielded on all sides other than the mating face.

19. The method of claim 17, wherein the magnetic heatsink assembly comprises:
at least one fan-receiving fin group defining an inter-fin channel between a left and a right fan-receiving fin, each having an inwardly curved side extension, and
the method further comprising:
inserting a micro fan cooling module into the inter-fin channel so that the inwardly curved side extensions laterally guide the micro fan cooling module and engaging an underside portion of the micro fan cooling module with a protruding lip of a bottom slot located at a bottom center region of the inter-fin channel to provide three-way mechanical locking.

20. The method of claim 17, further comprising:
disposing a thermal interface between a bottom surface of the heatsink base and a top surface of the SPS board.
